(19) United States
(12) Patent Application Publication
(10) Pub. No.: US 2012/0092078 A1
(43) Pub. Date: Apr. 19, 2012

(54) VARIABLE RESISTOR CIRCUIT AND OSCILLATION CIRCUIT

(76) Inventor: Yasukazu KAI, Miyazaki (JP)

(21) Appl. No.: 13/233,611

(22) Filed: Sep. 15, 2011

(30) Foreign Application Priority Data
Oct. 13, 2010 (JP) 2010-230605

(51) Int. Cl. H03B 7/14; H02B 1/00

(52) U.S. Cl. 331/107 R; 307/115

(57) ABSTRACT

A variable resistor circuit is arranged to adjust a resistivity value between a first terminal and a second terminal thereof according to a control signal. The variable resistor circuit includes a first resistivity adjusting circuit and a second resistivity adjusting circuit. The first resistivity adjusting circuit includes a first series resistor circuit formed of a plurality of resistor elements and a first switch portion for selectively connecting one of specific nodes of the first series resistor circuit to the first terminal according to the control signal. The second resistivity adjusting circuit includes a second series resistor circuit formed of a plurality of resistor elements connected to the second terminal and a second switch portion for selectively connecting the first series resistor circuit to one of specific nodes of the second series resistor circuit according to the control signal.

### BACKGROUND OF THE INVENTION AND RELATED ART STATEMENT

The present invention relates to a variable resistor circuit and an oscillation circuit having the variable resistor circuit.

A conventional oscillation circuit for outputting a square pulse includes a CR oscillation circuit using the Schmitt inverter. The conventional oscillation circuit outputs the square pulse having an oscillation frequency according to a time constant determined by a resistivity value of a resistor element and a capacitance value of a capacitor of the CR oscillation circuit.

In order to accurately obtain the oscillation frequency of the conventional oscillation circuit, it may be configured such that at least one of the resistivity value of the resistor element and the capacitance value of the capacitor variable is variable. Accordingly, it is possible to adjust one of the resistivity value of the resistor element and the capacitance value of the capacitor variable to obtain the oscillation frequency.

Patent Reference 1 has disclosed such a conventional oscillation circuit. The conventional oscillation circuit disclosed in Patent Reference 1 includes a counter unit for counting a pulse number of a clock within a specific period of time measured according to a standard clock; a storage unit for storing a plurality of trimming data, and for retrieving the trimming data according to the pulse number counted with the counter unit; and a trimming unit for adjusting a resistivity value and a capacitance value according to the trimming data thus retrieved.

Patent Reference 2 has disclosed a conventional circuit, although not an oscillation circuit. The conventional circuit disclosed in Patent Reference 2 includes a resistor ladder circuit formed of a plurality of resistors connected in series between a power source voltage and a ground potential; and a trimming block formed of a switch element group connected in a tree arrangement to the resistor ladder circuit. Accordingly, in the conventional circuit disclosed in Patent Reference 2, it is possible to obtain a desired output voltage. In the trimming block, a switch element is turned on according to a trimming signal supplied thereto, so that the desired voltage is extracted from an arbitrary node of the resistor ladder circuit.
Patent Reference 1: Japanese Patent Publication No. 2006-229630
Patent Reference 2: Japanese Patent Publication No. 2008-140961

In recent years, as functions of various digital devices have been advanced, there has been a need to develop an oscillation circuit having a high accuracy of an oscillation frequency property. In addition, there has been an additional need to reduce a size and a cost of the digital devices. When a crystal oscillator or a ceramic oscillator is used, it is possible to obtain an oscillation circuit having a high accuracy of an oscillation frequency property. However, it is necessary to provide the crystal oscillator or the ceramic oscillator outside an IC (Integrated Circuit) as an external component, thereby making it difficult to reduce the size and the cost of the digital devices.

As disclosed in Patent Reference 1, the conventional oscillation circuit is formed of a plurality of resistor elements and capacitors, so that the resistor elements and the capacitors are appropriately selected to adjust the oscillation frequency. Accordingly, it is possible to obtain the conventional oscillation circuit without using the crystal oscillator or the ceramic oscillator.

However, when the conventional oscillation circuit is formed of the IC, the capacitors tend to occupy a large area inside the IC. Accordingly, when the capacitors with various capacitance values are disposed inside the IC, it is difficult to reduce a chip area of the IC. In order to reduce the chip area of the IC, a small number of the capacitors may be disposed inside the IC. In this case, however, it is possible to adjust the oscillation frequency only within a limited adjustable range. Further, it is difficult to accurately adjust the oscillation frequency due to a deteriorated frequency adjustment resolution.

In the conventional oscillation circuit, when the capacitance value of the capacitors is fixed, it is necessary to increase the number of the resistor elements, so that the oscillation frequency can be accurately adjusted. However, when the switch element group in the tree arrangement is used to select the resistivity value as in the conventional circuit disclosed in Patent Reference 2, a scale of the switch element group tends to increase with the number of the resistor elements. When the number of the resistor elements increases, the switch elements in a plurality of stages are disposed in a current path. Accordingly, when the switch element is formed of, for example, a transistor, the transistor tends to have a large on resistance.

Accordingly, when the trimming block disclosed in Patent Reference 2 is applied to the CR oscillation circuit, the accuracy of the oscillation frequency tends to be deteriorated due to the on resistance of the switch element. Further, the on resistance of the transistor tends to be affected by a variance in a thresh voltage and a fluctuation of a voltage or a temperature, thereby causing a variance in the oscillation frequency.

In view of the problems described above, an object of the present invention is to provide a variable resistor circuit capable of solving the problems of the conventional variable resistor circuit. In the present invention, it is possible to reduce a circuit size of the variable resistor circuit, and to accurately adjust a resistivity value of the variable resistor circuit. Further, when an oscillation circuit includes the variable resistor circuit, it is possible to reduce a circuit size of the oscillation circuit, and to obtain an oscillation frequency having a high accuracy.

Further objects and advantages of the invention will be apparent from the following description of the invention.

### SUMMARY OF THE INVENTION

In order to attain the objects described above, according to a first aspect of the present invention, a variable resistor circuit is arranged to adjust a resistivity value between a first terminal and a second terminal thereof according to a control signal. The variable resistor circuit includes a first resistivity adjusting circuit and a second resistivity adjusting circuit. The first resistivity adjusting circuit includes a first series resistor circuit formed of a plurality of resistor elements and a first switch portion for selectively connecting one of specific nodes of the first series resistor circuit to the first terminal according to the control signal. The second resistivity adjusting circuit includes a second series resistor circuit formed of a plurality of resistor elements connected to the second terminal and a second switch portion for selectively connecting the first series resistor circuit to one of specific nodes of the second series resistor circuit according to the control signal.

According to a second aspect of the present invention, an oscillation circuit includes the variable resistor circuit described above.

According to the present invention, in the variable resistor circuit, it is possible to reduce a circuit size thereof, and to accurately adjust a resistivity value thereof. Further, in the oscillation circuit, it is possible to reduce a circuit size thereof, and to accurately adjust an oscillation frequency thereof.

### BRIEF DESCRIPTION OF THE DRAWINGS

FIG. 1 is a block diagram showing a configuration of an oscillation circuit according to an embodiment of the present invention;

FIG. 2 is a timing chart showing an operation of the oscillation circuit according to the embodiment of the present invention;

FIG. 3 is a block diagram showing a configuration of a variable resistor circuit of the oscillation circuit according to the embodiment of the present invention;

FIG. 4 is a block diagram showing a configuration of a switch circuit of the variable resistor circuit according to the embodiment of the present invention;

FIG. 5 is a block diagram showing a configuration of a variable resistor circuit of an oscillation circuit according to a comparative example No. 1;

FIG. 6 is a block diagram showing a configuration of a switch circuit of the variable resistor circuit according to the comparative example No. 1; and

FIG. 7 is a block diagram showing a configuration of a variable resistor circuit of an oscillation circuit according to a comparative example No. 2.

### DETAILED DESCRIPTION OF PREFERRED EMBODIMENTS

Hereunder, preferred embodiments of the present invention will be explained with reference to the accompanying drawings. In the following drawings, substantially identical components or similar components are designated with the same reference numerals.

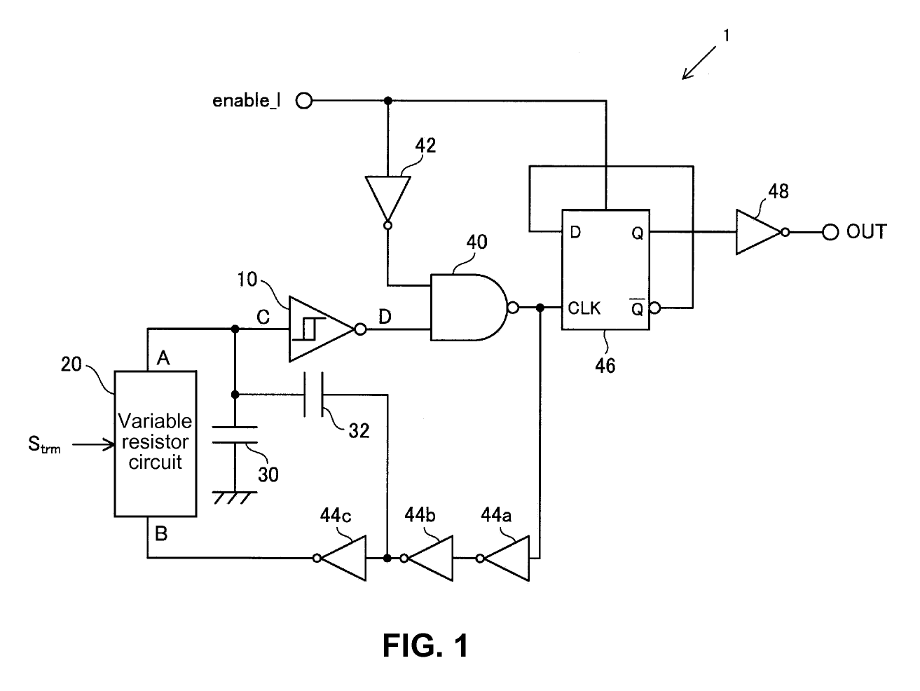

FIG. 1 is a block diagram showing a configuration of an oscillation circuit 1 according to an embodiment of the present invention.

As shown in FIG. 1, the oscillation circuit 1 includes a Schmitt inverter 10, a variable resistor circuit 20, and capacitors 30 and 32. The Schmitt inverter 10 has an input terminal C connected to one terminal A of the variable resistor circuit 20 and terminals of the capacitors 30 and 32. The variable resistor circuit 20 is formed of a plurality of resistor elements, and is configured such that a resistivity value between terminals A and B can be adjusted according to a trimming signal Strm supplied externally (described later). Another terminal of the capacitor 30 is connected to a ground potential, and another terminal of the capacitor 32 is connected to an output terminal of an inverter 44b.

In the embodiment, an output terminal D of the Schmitt inverter 10 is connected to one input terminal of an NAND circuit 40. An enable signal is supplied to another input terminal of the NAND circuit 40 through an inverter 42. It is noted that the enable signal is a control signal for controlling whether an output of the oscillation circuit 1 is valid or invalid.

In the embodiment, an output terminal of the NAND circuit 40 is connected to a clock input terminal CLK of a flip-flop circuit 46, and is further connected to a terminal B of the variable resistor circuit 20 through inverters 44a, 44b, and 44c. The flip-flop circuit 46 is a T-type flip-flop circuit configured to perform a toggle operation relative to a clock input. An output terminal Q of the flip-flop circuit 46 is connected to an output terminal OUT through an inverter 48.

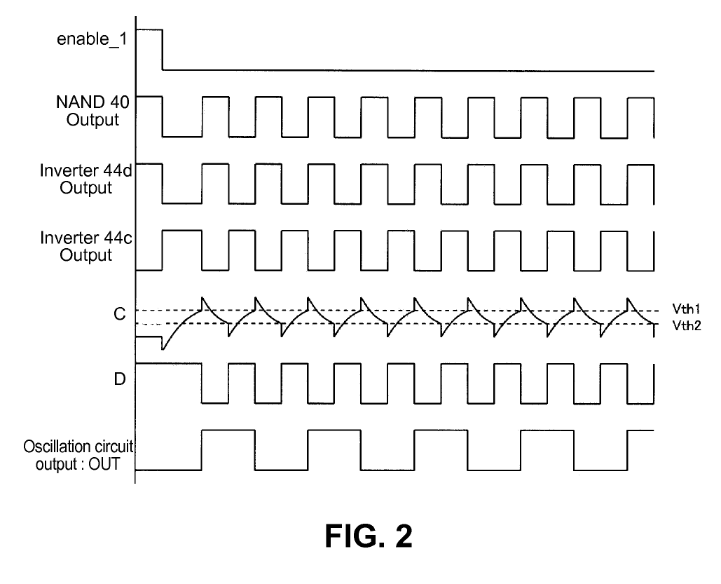

An operation of the oscillation circuit 1 will be explained next with reference to a timing chart shown in FIG. 2. FIG. 2 is the timing chart showing the operation of the oscillation circuit 1 according to the embodiment of the present invention.

In the embodiment, the Schmitt inverter 10 has two threshold voltages Vth1 and Vth2 having different voltage levels. When the oscillation circuit 1 is turned on, and the enable signal becomes a low level indicating that the output of the oscillation circuit 1 is valid, an output of the NAND circuit 40 becomes the low level. Accordingly, an output of the inverter 44b becomes the low level, and an output of the inverter becomes a high level, so that the capacitors 30 and 32 start being charged through the variable resistor circuit 20.

As a result, an input voltage of the Schmitt inverter 10 increases at a change rate determined by a CR time constant. When the input voltage of the Schmitt inverter 10 reaches the threshold voltage Vth1, the output of the Schmitt inverter 10 is changed to the low level. Accordingly, the output of the NAND circuit 40 becomes the high level, the output of the inverter 44b becomes the high level, and the output of the inverter 44c becomes the low level, respectively. As a result, electric charges charged in the capacitors 30 and 32 are discharged through the variable resistor circuit 20.

In the next step, the input voltage of the Schmitt inverter 10 decreases at a change rate determined by the CR time constant. When the input voltage of the Schmitt inverter 10 reaches the threshold voltage Vth2, the output of the Schmitt inverter 10 is changed to the high level, so that the capacitors 30 and 32 start being charged again. In the embodiment, the Schmitt inverter 10 repeats the operation described above, so that the Schmitt inverter 10 outputs a square pulse having a specific oscillation frequency. When the resistivity value between the terminals A and B of the variable resistor circuit 20 is changed according to the trimming signal Strm, the oscillation frequency of the output signal of the Schmitt inverter 10 is changed.

In the embodiment, the output signal of the Schmitt inverter 10 is input into the clock input terminal of the flip-flop circuit 46 through the NAND circuit 40. The NAND circuit 40 is configured to output an output signal obtained through inverting the output of the Schmitt inverter 10 during a period of time when the enable signal is the low level indicating that the output of the oscillation circuit 1 is valid. As explained above, the flip-flop circuit 46 is the T-type flip-flop circuit, so that the flip-flop circuit 46 performs the toggle operation for inverting the output signal from a previous state per rising edge of the clock input. The output signal of the flip-flop circuit 46 is output to the output terminal OUT through the inverter 48. A square pulse synchronized with the output signal of the Schmitt inverter 10 is output from the output terminal OUT.

In the embodiment, as described above, when the resistivity value between the terminals A and B of the variable resistor circuit 20 is changed according to the trimming signal Strm, the CR time constant is changed. Accordingly, the oscillation frequency of the output signal output from the output terminal OUT of the oscillation circuit 1 is changed.

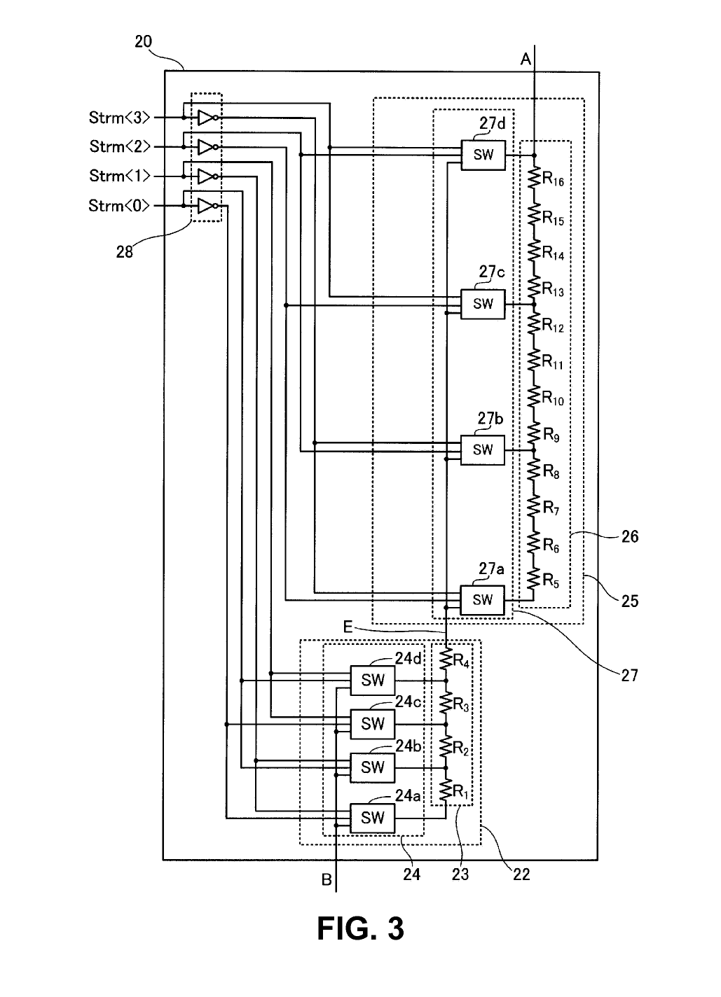

FIG. 3 is a block diagram showing a configuration of the variable resistor circuit 20 of the oscillation circuit 1 according to the embodiment of the present invention.

As shown in FIG. 3, the variable resistor circuit 20 includes a resistor circuit between the terminals A and B. The resistor circuit is formed of a plurality of resistor elements connected in series. The number of the resistor elements may be, for example, sixteen. Each of the resistor elements has an identical resistivity value r (Ω). It is noted that the resistivity value r (Ω) of each of the resistor elements can be arbitrarily specified. More specifically, the variable resistor circuit 20 is formed of two blocks, i.e., a first resistivity adjusting circuit 22 and a second resistivity adjusting circuit 25.

In the embodiment, the first resistivity adjusting circuit 22 includes a first series resistor circuit 23 on the side of the terminal B. The first series resistor circuit 23 is formed of, for example, four resistor elements R1 to R4 connected in series. Each of connecting points between adjacent resistor elements is connected to each of switch circuits 24b, 24c, and 24d, respectively. An end terminal of the resistor element R1 is not connected to other resistor elements, and is connected to a switch circuit 24a.

In the embodiment, nodes are connected to the switch circuits 24a to 24d. When the switch circuits 24a to 24d are turned on, the nodes are connected to the terminal B. It is noted that switch circuits 24a to 24d constitute a first switch portion 24.

In the embodiment, the second resistivity adjusting circuit 25 includes a second series resistor circuit 26 on the side of the terminal A. The second series resistor circuit 26 is formed of, for example, twelve resistor elements R5 to R16 connected in series. An end terminal of the resistor element R16 is not connected to other resistor elements, and is connected to a switch circuit 27d. Each of connecting points between the resistor elements R8 and R9 and the resistor elements R12 and R13 is connected to each of switch circuits 27b and 24c, respectively. An end terminal of the resistor element R5 is not connected to other resistor elements, and is connected to a switch circuit 27a.

In the embodiment, nodes are connected to the switch circuits 27a to 27d. When the switch circuits 27a to 27d are turned on, the nodes are connected to the first series resistor circuit 23 (the end terminal of the resistor element R4). It is noted that the switch circuits 27a to 27d constitute a second switch portion 27.

In the embodiment, the switch circuits 24a to 24d and the switch circuits 27a to 27d disposed in the first resistivity adjusting circuit 22 and the second resistivity adjusting circuit 25 are turned on or off according to the trimming signal Strm supplied externally. The trimming signal Strm may be, for example, a digital signal with four bits. In this case, lower two bits are supplied to the switch circuits 24a to 24d of the first resistivity adjusting circuit 22, and upper two bits are supplied to the switch circuits 27a to 27d of the second resistivity adjusting circuit 25. Each of the bits of the trimming signal Strm is divided to a path passing through the inverter 28 and a path not passing through the inverter 28, so that one bit generates two values “0” and “1”.

In the embodiment, the inverter 28 is provided corresponding to each of the bits of the trimming signal Strm. Accordingly, different two bits of the trimming signal Strm are supplied to the switch circuits 24a to 24d of the first resistivity adjusting circuit 22 according to every input.

More specifically, an inverted signal of the first bit and an inverted signal of the second bit of the trimming signal Strm are supplied to the switch circuit 24a. A non-inverted signal of the first bit and the inverted signal of the second bit of the trimming signal Strm are supplied to the switch circuit 24b. The inverted signal of the first bit and a non-inverted signal of the second bit of the trimming signal Strm are supplied to the switch circuit 24c. The non-inverted signal of the first bit and the non-inverted signal of the second bit of the trimming signal Strm are supplied to the switch circuit 24d.

For example, when the lower two bits of the trimming signal Strm are “11”, the trimming signal Strm “00” is supplied to the switch circuit 24a. Similarly, the trimming signal Strm “01” is supplied to the switch circuit 24b, the trimming signal Strm “10” is supplied to the switch circuit 24c, and the trimming signal Strm “11” is supplied to the switch circuit 24d.

In the embodiment, similarly, the inverter 28 is provided such that the different two bits of the trimming signal Strm are supplied to the switch circuits 27a to 27d of the second resistivity adjusting circuit 25 according to every input.

More specifically, an inverted signal of the third bit and an inverted signal of the fourth bit of the trimming signal Strm are supplied to the switch circuit 27a. A non-inverted signal of the third bit and the inverted signal of the fourth bit of the trimming signal Strm are supplied to the switch circuit 27b. The inverted signal of the third bit and a non-inverted signal of the fourth bit of the trimming signal Strm are supplied to the switch circuit 27c. The non-inverted signal of the third bit and the non-inverted signal of the fourth bit of the trimming signal Strm are supplied to the switch circuit 27d.

For example, when the upper two bits of the trimming signal Strm are “11”, the trimming signal Strm “00” is supplied to the switch circuit 27a. Similarly, the trimming signal Strm “01” is supplied to the switch circuit 27b, the trimming signal Strm “10” is supplied to the switch circuit 27c, and the trimming signal Strm “11” is supplied to the switch circuit 27d.

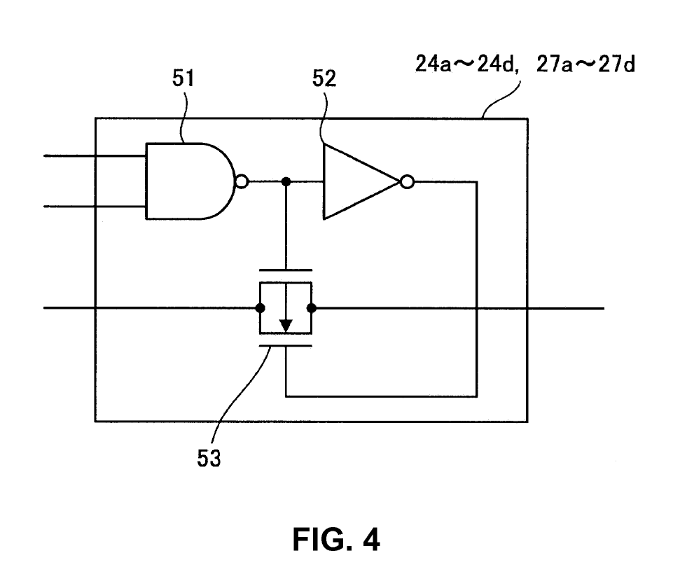

FIG. 4 is a block diagram showing a configuration of each of the switch circuits 24a to 24d and 27a to 27d of the variable resistor circuit 20 according to the embodiment of the present invention. It is noted that the switch circuits 24a to 24d and 27a to 27d have an identical configuration.

As shown in FIG. 4, each of the switch circuits 24a to 24d and 27a to 27d includes an NAND circuit 51, and inverter 52, and a transfer gate 53. The upper two bits or the lower two bits of the trimming signal Strm are supplied to the NAND circuit 51. When the two bits of the trimming signal Strm are input into the NAND circuit 51, the NAND circuit 51 outputs and supplied a negative NAND thereof to the inverter 52, and further to a gate of a PMOS constituting the transfer gate 53.

In the embodiment, the inverter 52 is provided for inverting the output signal of the NAND circuit 51, and for supplying the inverted signal to a gate of an NMOS constituting the transfer gate 53. The transfer gate 53 is a switch element for switching according to the gate input of the PMOS and the NMOS. Only when the input signal of the NAND circuit 51 is “11”, each of the switch circuits 24a to 24d and 27a to 27d is turned on.

In the embodiment, each of the switch circuits 24a to 24d and 27a to 27d has the configuration as explained above. With a signal dividing unit including the inverter 28 and the switch circuits 24a to 24d and 27a to 27d in the first resistivity adjusting circuit 22 and the second resistivity adjusting circuit 25, only one of the switch circuits 24a to 24d is turned on with respect to all inputs, and only one of the switch circuits 27a to 27d is turned on with respect to all inputs.

For example, when the trimming signal Strm is “1111”, only the switching circuit 24d is turned on in the first resistivity adjusting circuit 22, and only the switching circuit 27d is turned on in the second resistivity adjusting circuit 25. Other switching circuits are maintained in the off state, so that the resistivity between the terminals A and B becomes r (Ω) corresponding to a minimum value that the variable resistor circuit 20 is capable of setting.

In contrast, when the trimming signal Strm is “0000”, only the switching circuit 24a is turned on in the first resistivity adjusting circuit 22, and only the switching circuit 27a is turned on in the second resistivity adjusting circuit 25. Other switching circuits are maintained in the off state, so that the resistivity between the terminals A and B becomes 16r (Ω) corresponding to a maximum value that the variable resistor circuit 20 is capable of setting.

As described above, in the variable resistor circuit 20, only one of the switch circuits 24a to 24d in the first resistivity adjusting circuit 22 and only one of the switch circuits 27a to 27d in the second resistivity adjusting circuit 25 are turned on according to the trimming signal Strm. Accordingly, it is possible to change the resistivity between the terminals A and B from r (Ω) to 16r (Ω) with an increment of r (Ω).

As described above, in the embodiment, it is possible to adjust the resistivity of the variable resistor circuit 20. As a result, a charging time and a discharging time of the capacitors 30 and 32 are changed, thereby changing the oscillation frequency of the oscillation circuit 1.

In the embodiment described above, the number of the resistor elements R1 to R16 constituting the variable resistor circuit 20 is sixteen. The present invention is not limited thereto, and the number of the resistor elements may be appropriately increased or decreased depending on an adjustment range of the oscillation frequency of the oscillation circuit 1 and an adjustment increment (or an adjustment resolution) of the oscillation frequency of the oscillation circuit 1. Further, the number of the resistor elements R1 to R4 constituting the first resistivity adjusting circuit 22 and the number of the resistor elements R5 to R16 constituting the second resistivity adjusting circuit 25 may be appropriately increased or decreased.

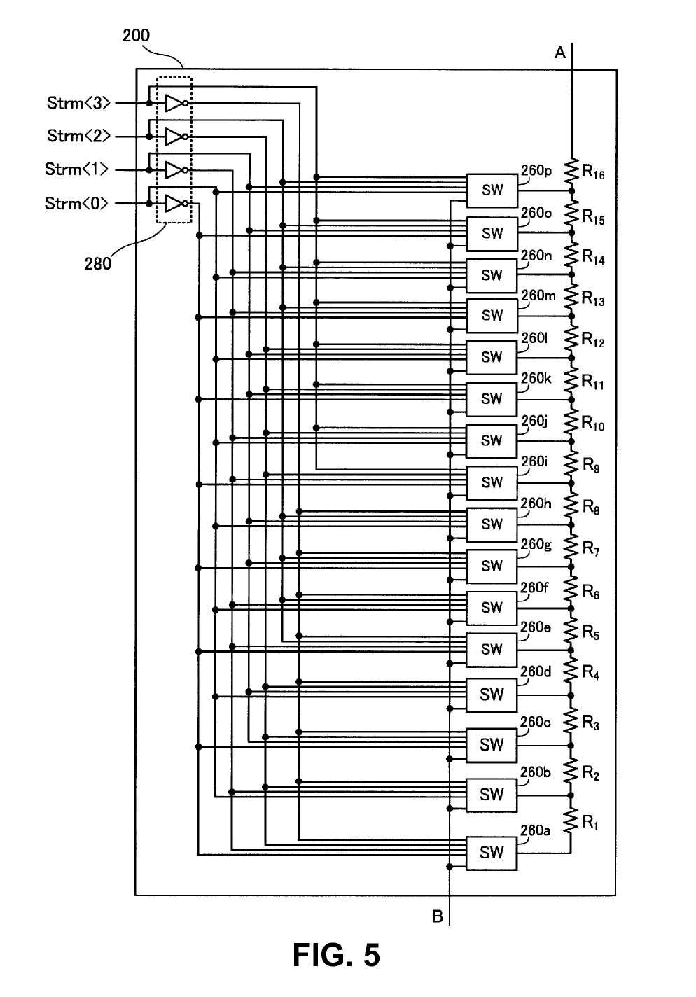

FIG. 5 is a block diagram showing a configuration of a variable resistor circuit 200 of an oscillation circuit according to a comparative example No. 1.

As shown in FIG. 5, the variable resistor circuit 200 includes a resistor circuit between the terminals A and B. The resistor circuit is formed of a plurality of resistor elements connected in series. The number of the resistor elements may be, for example, sixteen similar to the variable resistor circuit 20 in the embodiment of the present invention. Each of the resistor elements has an identical resistivity value r (Ω).

In the comparative example No. 1, an end terminal of the resistor element R1 is not connected to other resistor elements, and is connected to a switch circuit 260a. Further, nodes are connected to switch circuits 260a to 260p. When the switch circuits 260a to 260p are turned on, the nodes are connected to the terminal B. An end terminal of the resistor element R16 is not connected to other resistor elements, and is connected to the terminal A.

In the comparative example No. 1, the switch circuits 260a to 260p are turned on or off according to the trimming signal Strm supplied externally. The trimming signal Strm may be, for example, a digital signal with four bits. In this case, all four bits are supplied to the switch circuits 260a to 260p. Each of the bits of the trimming signal Strm is divided to a path passing through an inverter 280 and a path not passing through the inverter 280, so that one bit generates two values “0” and “1”.

Accordingly, in the comparative example No. 1, sixteen signals are generated from one trimming signal Strm, and are supplied to the switch circuits 260a to 260p, respectively. In other words, when on trimming signal Strm is input, different four bits of the trimming signal Strm are supplied to the switch circuits 260a to 260p.

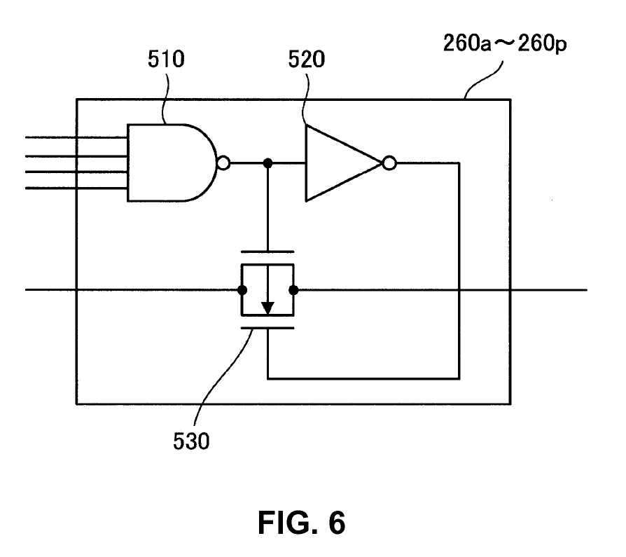

FIG. 6 is a block diagram showing a configuration of each of the switch circuits 260a to 260p of the variable resistor circuit 200 according to the comparative example No. 1. It is noted that the switch circuits 260a to 260p have an identical configuration.

As shown in FIG. 6, each of the switch circuits 260a to 260p includes an NAND circuit 510 having four input terminal different from the switch circuits 24a to 24d and 27a to 27d in the embodiment of the present invention. In the switch circuits 260a to 260p with the configuration described above, only when the input signal of the NAND circuit 510 is “1111”, the switch circuits 260a to 260p are turned on.

With a signal dividing unit including the inverter 280 and the switch circuits 260a to 260p, only one of the switch circuits 260a to 260p is turned on with respect to all inputs. For example, when the trimming signal Strm is “1111”, only the switching circuit 260p is turned on. Other switching circuits are maintained in the off state, so that the resistivity between the terminals A and B becomes r (Ω) corresponding to a minimum value that the variable resistor circuit 200 is capable of setting.

In contrast, when the trimming signal Strm is “0000”, only the switching circuit 260a is turned on. Other switching circuits are maintained in the off state, so that the resistivity between the terminals A and B becomes 16r (Ω) corresponding to a maximum value that the variable resistor circuit 200 is capable of setting.

As described above, in the variable resistor circuit 200, only one of the switch circuits 260a to 260p is turned on according to the trimming signal Strm. Accordingly, it is possible to change the resistivity between the terminals A and B from r (Ω) to 16r (Ω) with an increment of r (Ω).

When the variable resistor circuit 20 in the embodiment of the present invention is compared with the variable resistor circuit 200 in the comparative example No. 1, both the variable resistor circuit 20 and the variable resistor circuit 200 have the same adjustment range and the same adjustment resolution of the resistivity value as far as the variable resistor circuit 20 and the variable resistor circuit 200 have the same number and the same resistivity value of the resistor elements, thereby proving the same performance as the variable resistor circuit.

However, the variable resistor circuit 20 in the embodiment of the present invention has the configuration simpler than that of the variable resistor circuit 200 in the comparative example No. 1. More specifically, the variable resistor circuit 200 in the comparative example No. 1 includes sixteen of the switch circuits 260a to 260p, the same number as that of the resistor elements R1 to R16. On the other hand, the variable resistor circuit 20 in the embodiment of the present invention includes eight of the switch circuits 24a to 24d and 27a to 27d. Further, the variable resistor circuit 200 in the comparative example No. 1 includes the NAND circuit 280 having the four input terminals, whereas the variable resistor circuit 20 in the embodiment of the present invention includes the NAND circuit 28 having the two input terminals.

In the embodiment of the present invention, the variable resistor circuit 20 includes the two resistivity adjusting circuits, i.e., the first resistivity adjusting circuit 22 and the second resistivity adjusting circuit 25. Further, the four bits of the trimming signal Strm are divided, so that the two bits of the trimming signal Strm is supplied to the first resistivity adjusting circuit 22 and the second resistivity adjusting circuit 25, respectively. Further, in the first resistivity adjusting circuit 22, only one of the switching circuits 24a to 24d is turned on, thereby changing the resistivity by the increment r (Ω). In the second resistivity adjusting circuit 25, only one of the switching circuits 27a to 27d is turned on, thereby changing the resistivity by the increment 4r (Ω).

More specifically, in the second resistivity adjusting circuit 25, the switching circuits 27a to 27d are not disposed each of the connecting points of the resistor elements R5 to R16 arranged adjacently. As a result, it is configured to change the resistivity between the terminals A and B by the increment 4r (Ω) greater than that of the first resistivity adjusting circuit 22. In the variable resistor circuit 20, the resistivity between the terminals A and B is determined through the combination of the first resistivity adjusting circuit 22 and the second resistivity adjusting circuit 25. As a result, the variable resistor circuit 20 in the embodiment of the present invention has the adjustable range of the resistivity equivalent to that of the variable resistor circuit 200 in the comparative example No. 1.

As described above, the variable resistor circuit 20 in the embodiment of the present invention has the first resistivity adjusting circuit 22 and the second resistivity adjusting circuit 25, so that the four bits of the trimming signal Strm are divided and assigned to the first resistivity adjusting circuit 22 and the second resistivity adjusting circuit 25. Accordingly, as compared with the variable resistor circuit 200 in the comparative example No. 1, the variable resistor circuit 20 in the embodiment of the present invention is formed of the simpler configuration. Further, in the second resistivity adjusting circuit 25, the switching circuits 27a to 27d are not disposed each of the connecting points of the resistor elements R5 to R16 arranged adjacently. Accordingly, it is possible to reduce the number of the switching circuits, thereby making it possible to reduce the circuit scale.

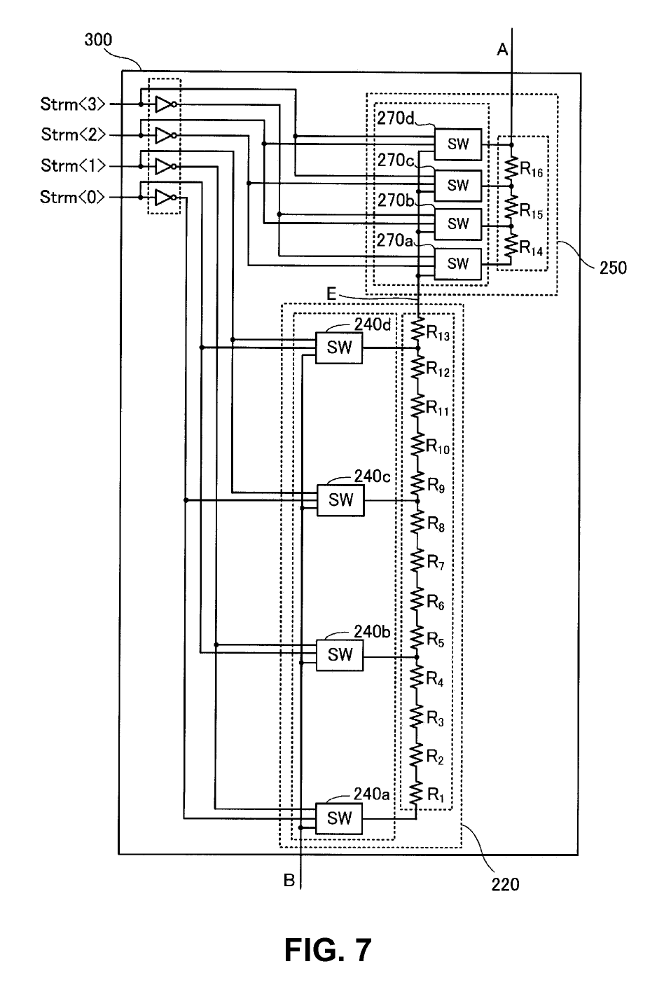

FIG. 7 is a block diagram showing a configuration of a variable resistor circuit 300 of an oscillation circuit according to a comparative example No. 2.

In the comparative example No. 2, the variable resistor circuit 300 includes a first resistivity adjusting circuit 220 and a second resistivity adjusting circuit 250. Different from the first resistivity adjusting circuit 22 and the second resistivity adjusting circuit 25 of the variable resistor circuit 20 in the embodiment of the present invention, the first resistivity adjusting circuit 220 includes switch circuits 240a to 240d connected to connecting points between specific ones of resistor elements R1 to R13. Further, the second first resistivity adjusting circuit 250 includes switch circuits 270a to 270d connected to connecting points between each of resistor elements R14 to R16.

In the variable resistor circuit 300 in the comparative example No. 2, when the trimming signal Strm is “0000”, only the switching circuit 240a is turned on in the first resistivity adjusting circuit 220, and only the switching circuit 270a is turned on in the second resistivity adjusting circuit 250. Other switching circuits are maintained in the off state, so that the resistivity between the terminals A and B becomes 16r (Ω).

In the variable resistor circuit 20 in the embodiment of the present invention, a resistivity value between the terminal B and a node E of a connecting point between the first resistivity adjusting circuit 22 and the second resistivity adjusting circuit 25 becomes 4r (Ω). On the other hand, in the variable resistor circuit 300 in the comparative example No. 2, a resistivity value between the terminal B and a node E of a connecting point between the first resistivity adjusting circuit 220 and the second resistivity adjusting circuit 250 becomes 13r (Ω).

When the resistivity value between the terminal B and the node E increases, a voltage drop at the node E becomes gentle. Accordingly, an on resistance of a transfer gate constituting the switch circuit connected to the node E have an large influence. To this end, in the variable resistor circuit 20 in the embodiment of the present invention, the resistivity value of the first resistivity adjusting circuit 22 is decreased, thereby reducing the influence of the on resistance of the transfer gate.

As described above, in the oscillation circuit 1 using the variable resistor circuit 20 in the embodiment of the present invention, the resistivity value of the variable resistor circuit 20 is changed according to the trimming signal Strm. Accordingly, it is possible to accurately obtain the oscillation frequency without using a crystal oscillator or a ceramic oscillator. Further, the capacitance value of the oscillation circuit 1 is fixed, and the oscillation frequency is changed only through changing the resistivity value. Accordingly, it is not necessary to dispose a large number of capacitors having a large occupied area in an IC, thereby making it possible to prevent a chip size from increasing.

Further, in the variable resistor circuit 20 in the embodiment of the present invention, the first resistivity adjusting circuit 22 and the second resistivity adjusting circuit 25 are configured and combined to have the different adjustment resolutions of the resistivity value. Accordingly, it is possible to reduce the circuit scale without compromising the adjustment range or the adjustment resolution of the resistivity value as a whole. In other words, in the variable resistor circuit 20, even when a large number of the resistor elements are disposed, it is still possible to reduce the scale of the switching circuits (the selection circuits) for selecting the resistivity value.

Further, in the variable resistor circuit 20 in the embodiment of the present invention, it is configured such that only one of the switching circuits 24a to 24d is turned on in the first resistivity adjusting circuit 22, and only one of the switching circuits 27a to 27d is turned on in the second resistivity adjusting circuit 25. In other words, only two switching circuits are involved in forming the charging or discharging current path. Accordingly, as compared with a switching circuit using multi-stage switching elements connected in a tree arrangement, it is possible to minimize the influence of the on resistance of the transistor.

As described above, in the variable resistor circuit 20 in the embodiment of the present invention, it is possible to reduce the circuit scale, and to accurately adjust the resistivity value. When the oscillation circuit 1 is provided with the variable resistor circuit 20, it is possible to accurately adjust the oscillation frequency while reducing the circuit scale.

In the embodiment, the variable resistor circuit 20 is disposed in the oscillation circuit 1. Alternatively, the variable resistor circuit 20 may be applicable to other circuits such as a reference voltage generation circuit and an amplifier circuit.

The disclosure of Japanese Patent Application No. 2010-230605, filed on Oct. 13, 2010, is incorporated in the application by reference.

While the invention has been explained with reference to the specific embodiments of the invention, the explanation is illustrative and the invention is limited only by the appended claims.

What is claimed is:

1. A variable resistor circuit for adjusting a resistivity value between a first terminal and a second terminal thereof according to a control signal, comprising:
a first resistivity adjusting circuit including a first series resistor circuit and a first switch portion, said first series resistor circuit being formed of a plurality of first resistor elements connected at first nodes, said first switch portion being arranged to selectively connecting one of the first nodes to the first terminal according to the control signal; and
a second resistivity adjusting circuit including a second series resistor circuit and a second switch portion, said second series resistor circuit being formed of a plurality of second resistor elements connected at second nodes and connected to the second terminal, said second switch portion being arranged to selectively connect the first series resistor circuit to one of the second nodes according to the control signal.

2. The variable resistor circuit according to claim 1, wherein said first resistivity adjusting circuit is arranged to adjust the resistivity value between the first terminal and the second terminal by an increment smaller than that of the second resistivity adjusting circuit.

3. The variable resistor circuit according to claim 1, wherein said first series resistor circuit is formed of the first resistor elements in a number smaller than that of the second resistor elements.

4. The variable resistor circuit according to claim 1, wherein said first switch portion includes a plurality of first switching circuits connected to the first nodes and an end portion of the first series resistor circuit so that one of the first switching circuits is turned on according to the control signal.

5. The variable resistor circuit according to claim 1, wherein said second switch portion includes a plurality of second switching circuits connected to the second nodes and an end portion of the second series resistor circuit so that one of the second switching circuits is turned on according to the control signal.

6. The variable resistor circuit according to claim 1, wherein said first series resistor circuit is arranged to receive the control signal including a digital signal formed of a plurality of upper bits and a plurality of lower bits so that the first switch portion receives the upper bits.

7. The variable resistor circuit according to claim 1, wherein said second series resistor circuit is arranged to receive the control signal including a digital signal formed of a plurality of upper bits and a plurality of lower bits so that the second switch portion receives the lower bits.

8. An oscillation circuit comprising the variable resistor circuit according to claim 1.
